(19) United States
(12) Patent Application Publication
(10) Pub. No.: US 2013/0075797 A1
(43) Pub. Date: Mar. 28, 2013

(54) SEMICONDUCTOR DEVICE AND METHOD OF MANUFACTURING THE SAME

(71) Applicant: Kimitoshi OKANO, Yokohama-shi (JP)

(72) Inventor: Kimitoshi OKANO, Yokohama-shi (JP)

(73) Assignee: KABUSHIKI KAISHA TOSHIBA, Tokyo (JP)

(21) Appl. No.: 13/599,025

(22) Filed: Aug. 30, 2012

(30) Foreign Application Priority Data
Sep. 22, 2011 (JP) 2011-207672

(51) Int. Cl. H01L 29/78; H01L 21/20

(52) U.S. Cl. 257/288; 438/478; 257/E29.255; 257/E21.09

(57) ABSTRACT

In one embodiment, a semiconductor device includes a semiconductor substrate, and a fin disposed on a surface of the semiconductor substrate and having a side surface of a (110) plane. The device further includes a gate insulator disposed on the side surface of the fin, and a gate electrode disposed on the side surface and an upper surface of the fin via the gate insulator. The device further includes a plurality of epitaxial layers disposed on the side surface of the fin in order along a height direction of the fin.

### CROSS REFERENCE TO RELATED APPLICATION

This application is based upon and claims the benefit of priority from the prior Japanese Patent Application No. 2011-207672, filed on Sep. 22, 2011, the entire contents of which are incorporated herein by reference.

### FIELD

Embodiments described herein relate to a semiconductor device and a method of manufacturing the same.

### BACKGROUND

In general, a plane orientation of a side surface channel of a finFET is a (100) plane or a (110) plane. Although the finFET having the (110) side surface channel has a higher hole mobility compared with the finFET having the (100) side surface channel, the finFET having the (110) side surface channel has a lower electron mobility compared with the finFET having the (100) side surface channel. However, when a stress is applied to the finFET having the (110) side surface channel, the electron mobility of the (110) side surface channel increases at a level comparable with the electron mobility of the (100) side surface channel. Therefore, the finFET having the (110) side surface channel is effective as a device for a CMOS. When the finFET having the (110) side surface channel is subjected to selective epitaxial growth (SEG) for reducing parasitic resistance in source and drain (S/D) regions, epitaxial layers having facet surfaces of (111) planes are formed on the (110) fin side surfaces of the S/D regions.

The increase of a height of fins in the finFET can increase the effective channel width of the finFET without increasing the footprint of the finFET. However, when the finFET having the (110) side surface channel is formed so that the fins have a high height and is subjected to the SEG, the epitaxial layers formed on the fins adjacent to each other are short-circuited before the SEG is well progressed.

On the other hand, when the SEG is stopped in the middle of the process to prevent the short-circuit, the short-circuit of the fins adjacent to each other can be prevented but the surface areas of the epitaxial layers are reduced. As a result, contact areas between the epitaxial layers and silicide layers are reduced, and therefore the reducing effect of the parasitic resistance in the S/D regions is lowered.

### BRIEF DESCRIPTION OF THE DRAWINGS

FIGS. 1A to 1C are a plan view and sectional views showing a structure of a semiconductor device of a first embodiment;

FIGS. 2A to 19B are sectional views showing a method of manufacturing the semiconductor device of the first embodiment;

FIGS. 20A to 20C are a plan view and sectional views showing a structure of a semiconductor device of a second embodiment;

FIGS. 21A to 24B are sectional views showing a method of manufacturing the semiconductor device of the second embodiment;

FIGS. 25A and 25B are sectional views showing the method of manufacturing the semiconductor device of the second embodiment in detail;

FIGS. 26A to 26C are a plan view and sectional views showing a structure of a semiconductor device of a third embodiment;

FIGS. 27A to 30B are sectional views showing a method of manufacturing the semiconductor device of the third embodiment; and

FIGS. 31A to 31C are a plan view and sectional views showing a structure of a semiconductor device of a modification of the third embodiment.

### DETAILED DESCRIPTION

Embodiments will now be explained with reference to the accompanying drawings.

In one embodiment, a semiconductor device includes a semiconductor substrate, and a fin disposed on a surface of the semiconductor substrate and having a side surface of a (110) plane. The device further includes a gate insulator disposed on the side surface of the fin, and a gate electrode disposed on the side surface and an upper surface of the fin via the gate insulator. The device further includes a plurality of epitaxial layers disposed on the side surface of the fin in order along a height direction of the fin.

### First Embodiment

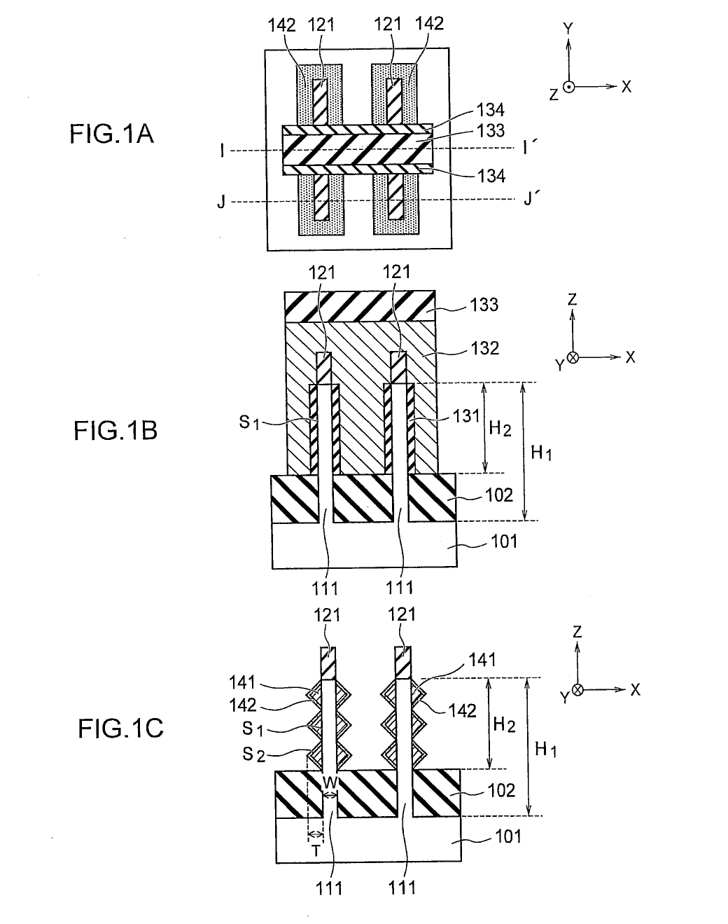

FIGS. 1A to 1C are a plan view and sectional views showing a structure of a semiconductor device of a first embodiment. FIG. 1A is a plan view showing a planar structure of the semiconductor device, and FIGS. 1B and 1C are sectional views taken along line I-I′ and line J-J′ shown in FIG. 1A, respectively.

The semiconductor device shown in FIGS. 1A to 1C includes, as components of a finFET, a semiconductor substrate 101, fins 111, hard mask layers 121, gate insulators 131, a gate electrode 132, a cap layer 133, sidewall insulators 134, epitaxial layers 141, and silicide layers 142.

The semiconductor substrate 101 is, for example, a silicon substrate. FIGS. 1A to 1C show X and Y directions which are parallel to a main surface of the semiconductor substrate 101 and are perpendicular to each other, and a Z direction which is perpendicular to the main surface of the semiconductor substrate 101. FIGS. 1A to 1C show isolation insulators 102 formed on the surface of the semiconductor substrate 101 so as to embed a part of the fins 111 in the isolation insulators 102. The isolation insulators 102 are, for example, silicon oxide layers.

The fins 111 are formed on the surface of the semiconductor substrate 101. FIGS. 1A to 1C show two fins 111 forming the finFET. The fins 111 extend in the Y direction and are adjacent to each other in the X direction. The Z direction corresponds to the height direction of the fins 111. The fins 111 of the present embodiment are formed by etching surface portions of the semiconductor substrate 101.

Reference character S₁ denotes side surfaces of the fins 111. The side surfaces S₁ are (110) planes. Reference character H₁ denotes the height of the fins 111, and reference character H₂ denotes the height of portions of the fins 111 exposed from the isolation insulators 102. The height H₂ is, for example, 50 nm or more. Reference character W denotes the width of the fins 111 in the X direction.

The hard mask layers 121 are formed on upper surfaces of the fins 111. The hard mask layers 121 are, for example, silicon nitride layers.

As shown in FIG. 1B, the gate insulators 131 are formed on the side surfaces of the fins 111. In addition, the gate electrode 132 is formed on the side surfaces and the upper surfaces of the fins 111 via the gate insulators 131 and the hard mask layers 121. More specifically, the gate electrode 132 is formed on the side surfaces of the fins 111 via the gate insulators 131, and on the upper surfaces of the fins 111 via the hard mask layers 121. The gate insulators 131 are, for example, silicon oxide layers. The gate electrode 132 is, for example, a polysilicon layer.

The cap layer 133 is formed on the upper surface of the gate electrode 132. The sidewall insulators 134 are formed on Y-directional side surfaces of the gate electrode 132 and the cap layer 133, as shown in FIG. 1A. The cap layer 133 is, for example, a silicon nitride layer. The sidewall insulators 134 are, for example, silicon nitride layers.

FIG. 1B is a sectional view of the fins 111 cut along the line I-I′ which crosses the gate insulators 131 and the gate electrode 132, while FIG. 1C is a sectional view of the fins 111 cut along the line J-Y which crosses the source or drain (S/D) regions in the fins 111.

As shown in FIG. 1C, the epitaxial layers 141 have triangular sectional shapes, and are formed on the side surfaces S₁ of the fins 111. In the present embodiment, three epitaxial layers 141 are formed on each side surface S₁ of each fin 111 in order along the Z direction. The epitaxial layers 141 are, for example, silicon layers.

In FIG. 1C, reference character S₂ denotes facet surfaces of the epitaxial layers 141. The facet surfaces S₂ are (111) planes. Reference character T denotes the thickness of the epitaxial layers 141, that is, the distance between the side surfaces S₁ of the fins 111 and the vertices of the epitaxial layers 141. The thickness T in the present embodiment is 15 to 25 nm (e.g., 20 nm).

In the present embodiment, three epitaxial layers 141 are formed on each side surface S₁ of the fins 111, but the number of the epitaxial layers 141 formed on each side surface S₁ may be two, or may be four or more.

The silicide layers 142 are formed in the epitaxial layers 141 in the vicinity of the facet surfaces S₂. The thickness of the silicide layers 142 in the present embodiment is 5 to 15 nm (e.g., 10 nm). Each epitaxial layer 141 may be silicided entirely, or may be only silicided partially. Alternatively, each epitaxial layer 141 may not be silicided.

As described above, a plurality of epitaxial layers 141 are formed on each side surface S₁ of the fins 111 in order along the Z direction in the present embodiment. Such structure has the advantages as described below as compared with the case where only one epitaxial layer 141 is formed on each side surface S₁ of the fins 111. In the following, the former structure is referred to as a divided epitaxial layer structure, and the latter structure is referred to as a single epitaxial layer structure.

First, the divided epitaxial layer structure has an advantage that short-circuit between the fins 111 adjacent to each other can be avoided. In FIGS. 1A to 1C, the thickness of the epitaxial layers 141 is denoted by reference character T in the case where three epitaxial layers 141 are formed on each side surface S₁. When the divided epitaxial layer structure is replaced by the single epitaxial layer structure, the thickness of the epitaxial layers 141 become 3×T.

In this way, the thickness of the epitaxial layers 141 becomes large in the single epitaxial layer structure. For this reason, when the epitaxial layers 141 of the single epitaxial layer structure are formed by selective epitaxial growth (SEG) on the side surfaces S₁ of the fins 111 having a large height, the epitaxial layers 141 of the fins 111 adjacent each other are short-circuited before the SEG is well progressed.

On the contrary, the short-circuit between the epitaxial layers 141 of the fins 111 adjacent to each other can be avoided in the divided epitaxial layer structure by sufficiently increasing the number of divisions of the epitaxial layers 141.

Second, the divided epitaxial layer structure has an advantage that large surface areas of the epitaxial layers 141 can be secured. In the case of the divided epitaxial layer structure shown in FIGS. 1A to 1C, the surface areas of the epitaxial layers 141 of both side surfaces S₁ of each fin 111 is expressed by 12×T/cos(θ/2)×(the length of each fin). In this expression, reference character θ denotes the angle of the vertices of the epitaxial layers 141. The surface areas are the same as the surface areas in the case of the single epitaxial layer structure. On the other hand, when the SEG process is stopped in the middle of the process in the production of the single epitaxial layer structure, the surface areas become smaller than this value.

In this way, according to the divided epitaxial layer structure, it is possible to secure large surface areas equal to the surface areas of the single epitaxial layer structure in the case where the SEG is sufficiently progressed.

Therefore, according to the present embodiment, large surface areas of the epitaxial layers 141 can be secured while the short-circuit between the fins 111 adjacent to each other can be avoided.

The finFET of the present embodiment can be used, for example, as a cell array transistor for a semiconductor memory such as a magnetic random access memory (MRAM) of a spin torque transfer type. A transistor of such semiconductor memory is required to have a footprint smaller than a transistor for a logic LSI and to have performance equivalent to the performance of the transistor for the logic LSI.

According to the present embodiment, since it is possible to secure large surface areas of the epitaxial layers 141 in the state where the height of the fins 111 is set to be large, it is possible to realize high integration of transistors having high performance.

(1) Method of Manufacturing Semiconductor Device of First Embodiment

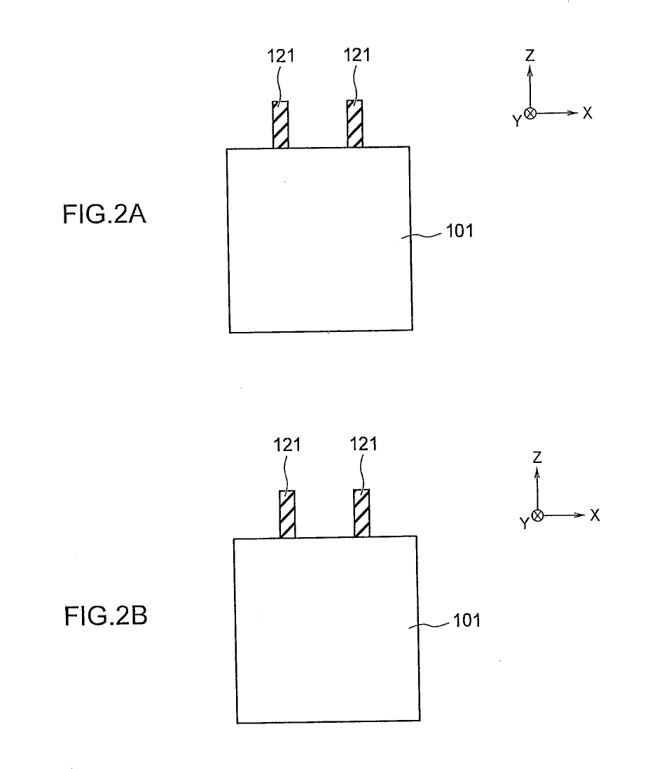

A method of manufacturing the semiconductor device of the first embodiment will now be described with reference to FIGS. 2A to 19B.

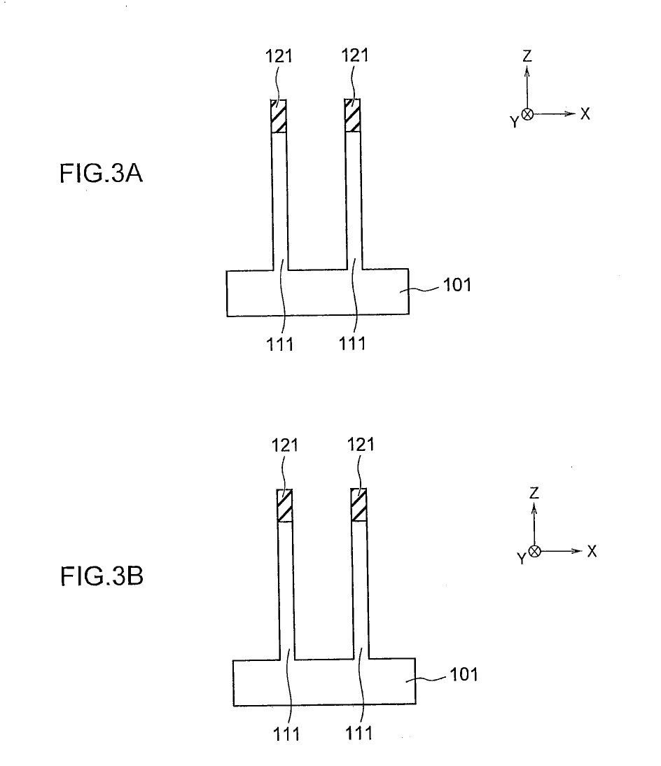

FIGS. 2A to 19B are sectional views showing the method of manufacturing the semiconductor device of the first embodiment. FIGS. 2A, 3A, . . . and 19A are sectional views taken along the line I-I′, and FIGS. 2B, 3B, . . . and 19B are sectional views taken along the line J-J′.

First, a hard mask layer 121 is deposited on the semiconductor substrate 101 (FIGS. 2A and 2B). Next, the hard mask layer 121 is processed into mask patterns for forming the fins 111 by lithography and reactive ion etching (RIE) (FIGS. 2A and 2B).

As shown in FIGS. 3A and 3B, surface portions of the semiconductor substrate 101 are then etched by RIE using the hard mask layers 121 as a mask. As a result, the fins 111 are formed on the surface of the semiconductor substrate 101. The fins 111 are formed so that the side surfaces S₁ become (110) planes.

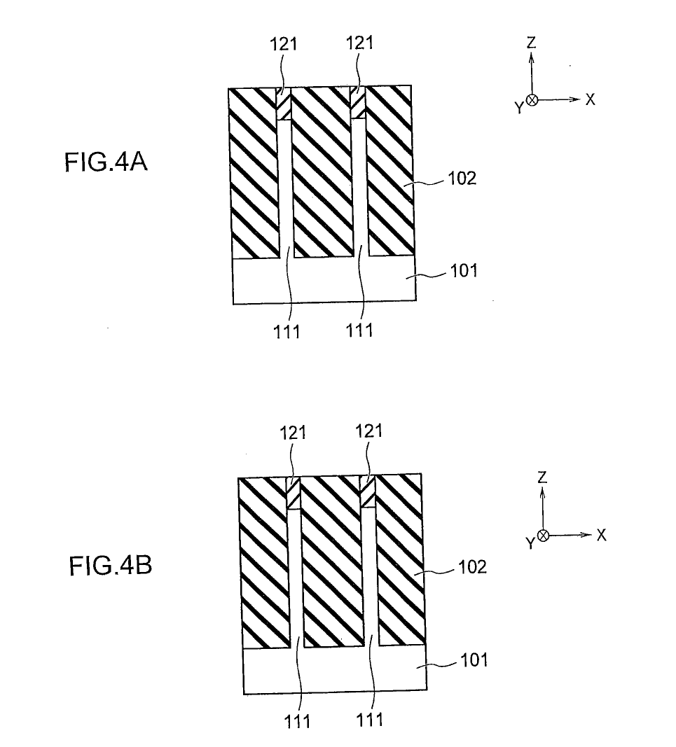

An insulator 102 to be a material of the isolation insulators 102 is then deposited on the entire surface of the semiconductor substrate 101 (FIGS. 4A and 4B). The surface of the insulator 102 is then planarized by chemical mechanical polishing (CMP), so that the insulators 102 are embedded between the fins 111 (FIGS. 4A and 4B).

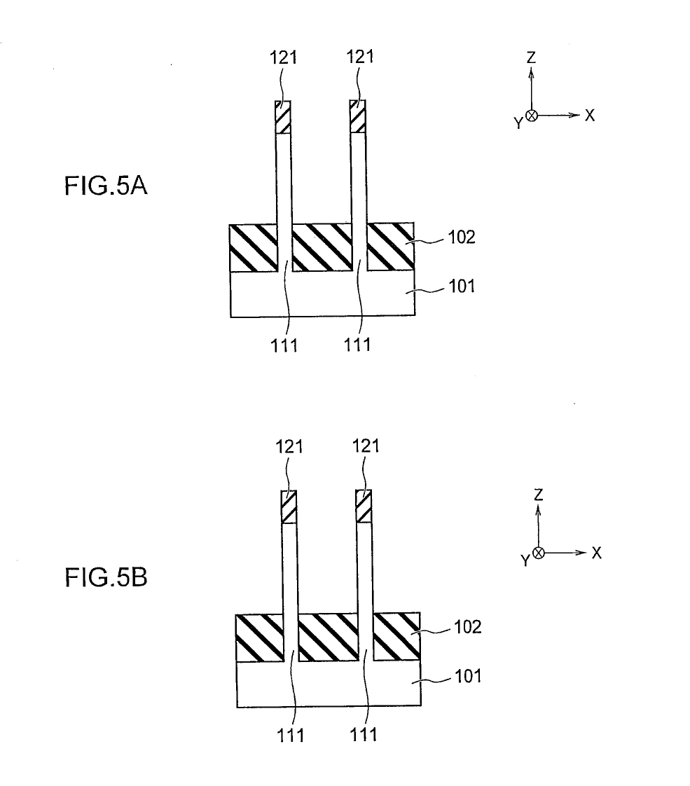

As shown in FIGS. 5A and 5B, surfaces of the insulators 102 are then lowered by wet etching. As a result, the isolation insulators 102 as shallow trench isolation (STI) insulators are formed on the semiconductor substrate 101.

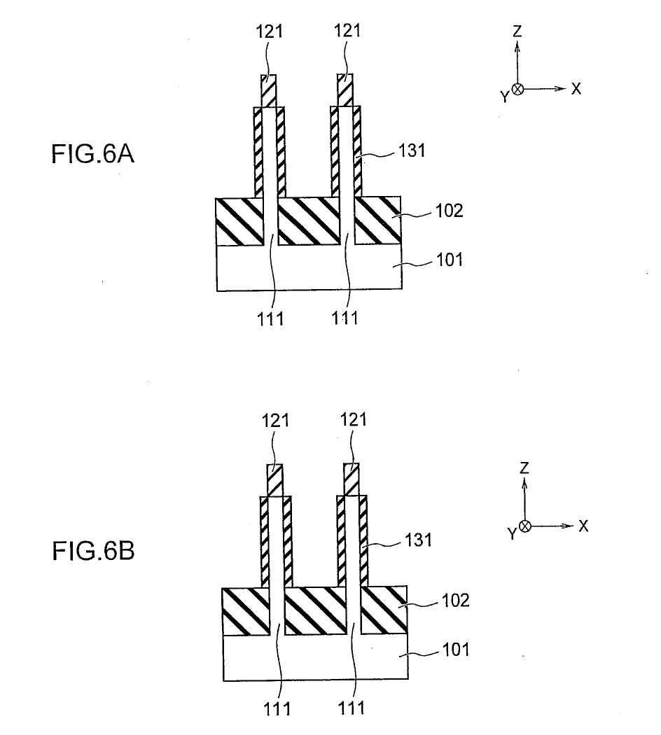

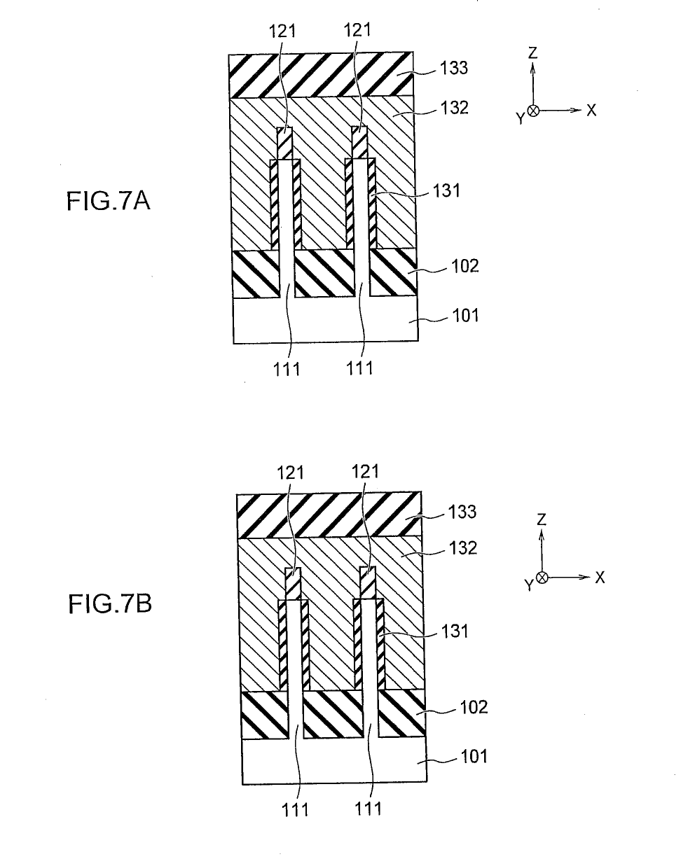

As shown in FIGS. 6A and 6B, insulators 131 to be the gate insulators 131 are then formed on the side surfaces of the fins 111 by thermal oxidation. As shown in FIGS. 7A and 7B, an electrode material 132 to be the gate electrode 132 and the cap layer 133 are then deposited in this order on the entire surface of the semiconductor substrate 101.

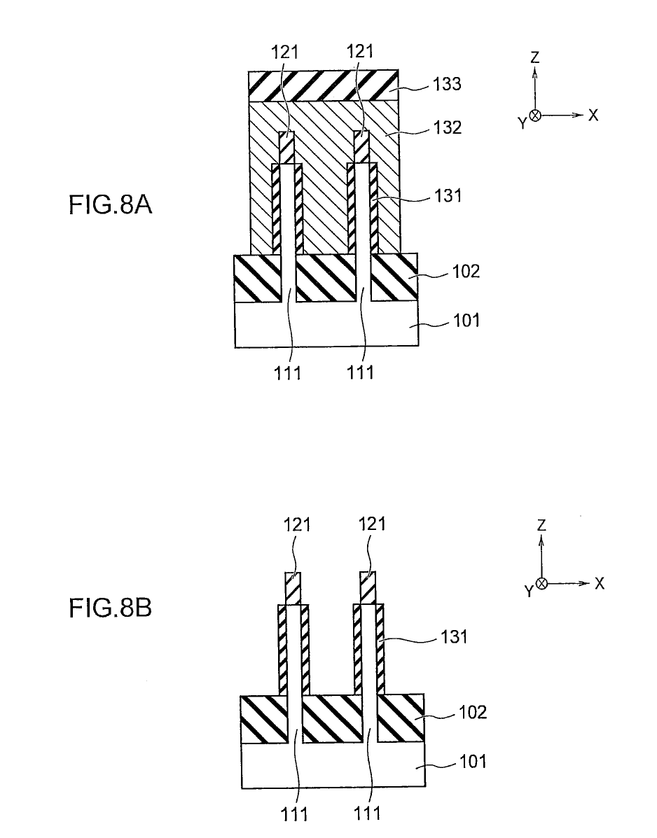

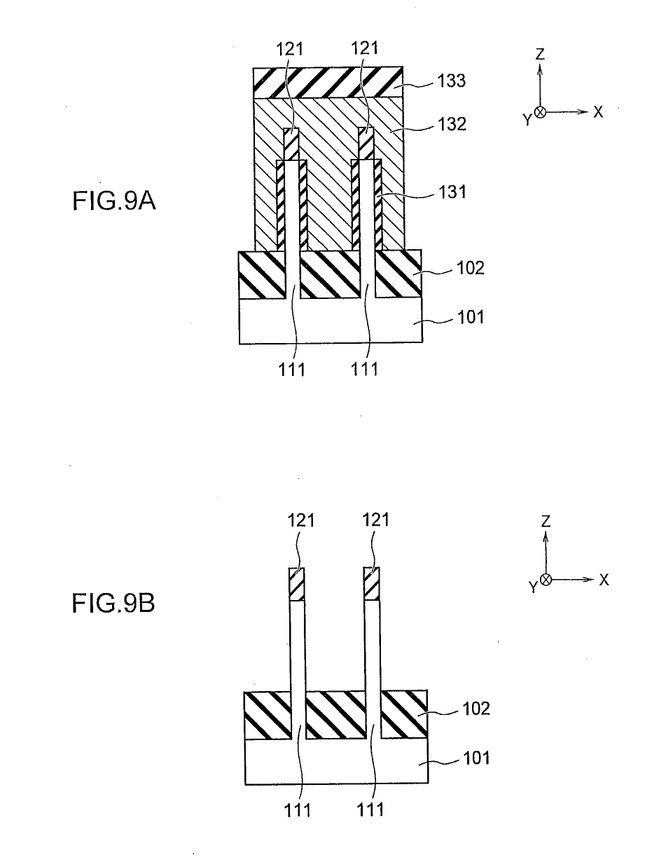

As shown in FIGS. 8A and 8B, after a hard mask of the gate electrode 132 is formed by processing the cap layer 133, the electrode material 132 is etched by RIE to form the gate electrode 132. It should be noted that the electrode material 132 is removed in FIG. 8B. As shown in FIGS. 9A and 9B, the insulators 131 formed on the side surfaces of the fins 111 in the S/D regions are then removed by wet etching. It should be noted that the insulators 131 are removed in FIG. 9B. In this way, the gate electrode 132 is formed on the side surfaces and the upper surfaces of the fins 111 via the gate insulators 131 and the hard mask layers 121.

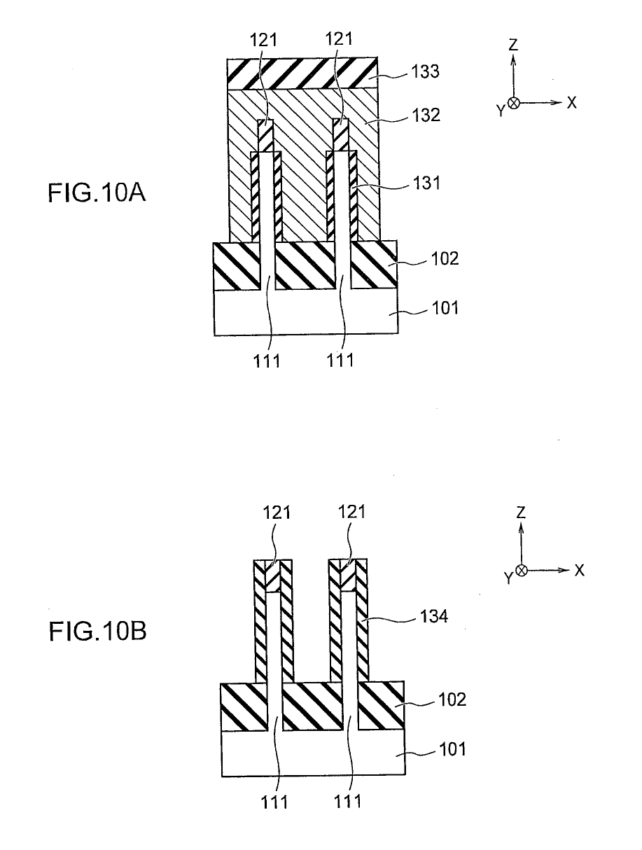

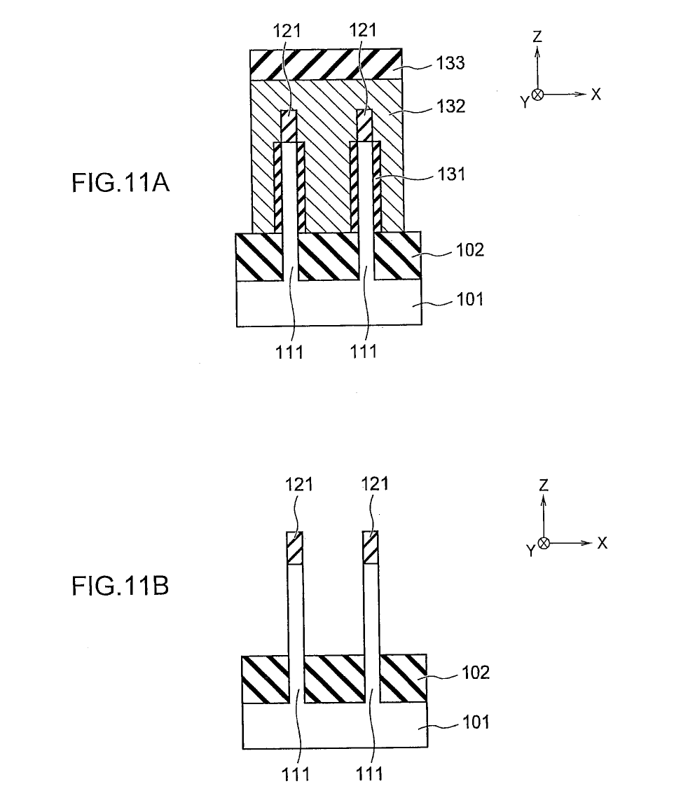

As shown in FIGS. 10A and 10B, the sidewall insulators 134 are then formed on the X-directional side surfaces of the fins 111, and on the Y-directional side surfaces of the gate electrode 132 and the cap layer 133 by chemical vapor deposition (CVD) and RIE. The former sidewall insulators 134 are shown in FIG. 10B, and the latter sidewall insulators 134 are shown in FIG. 1A. The former sidewall insulators 134 are removed by over etching using RIE as shown in FIGS. 11A and 11B.

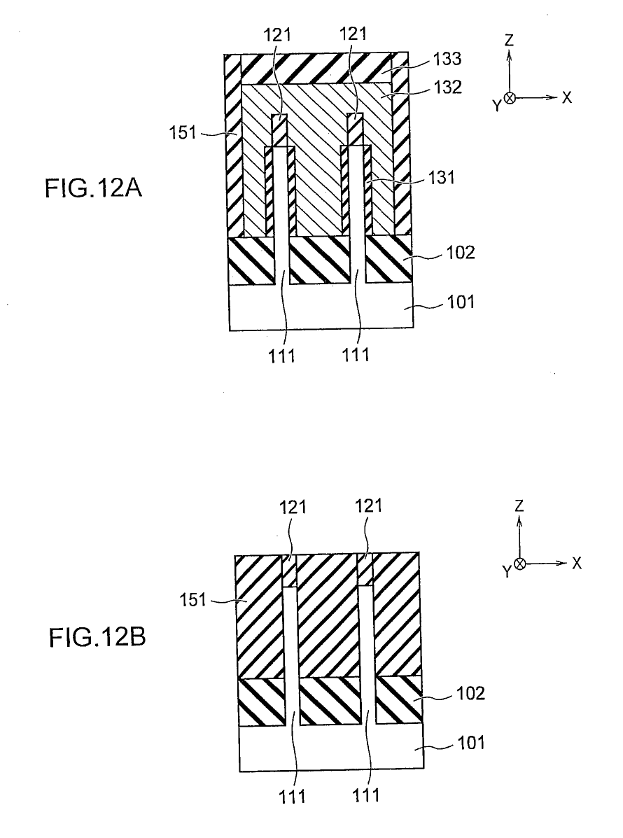

An insulator 151 to be used in processing for forming the epitaxial layers 141 is then deposited on the entire surface of the semiconductor substrate 101 (FIGS. 12A and 12B). As a result, the fins 111 are covered with the insulator 151. The insulator 151 is, for example, a silicon oxide layer.

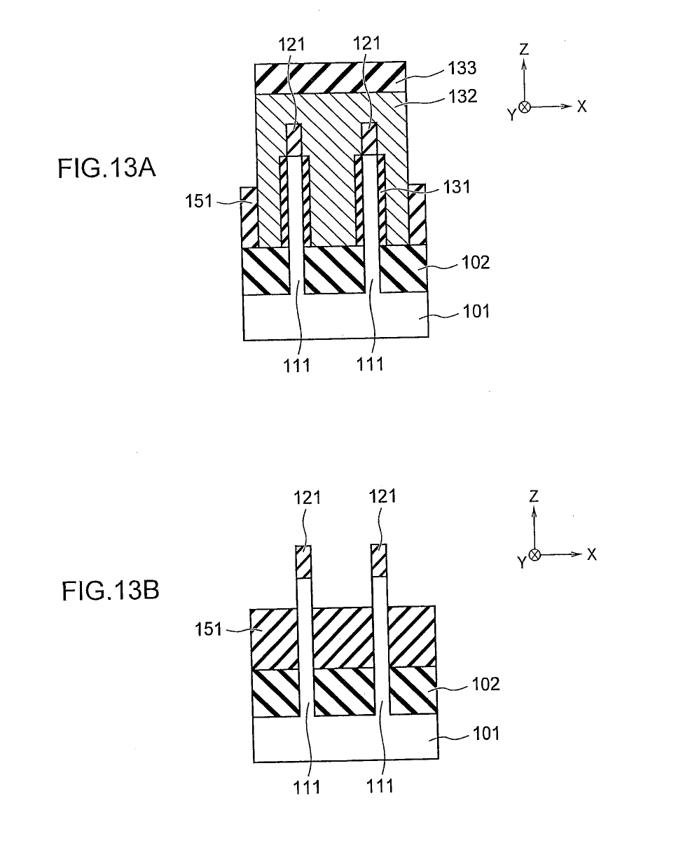

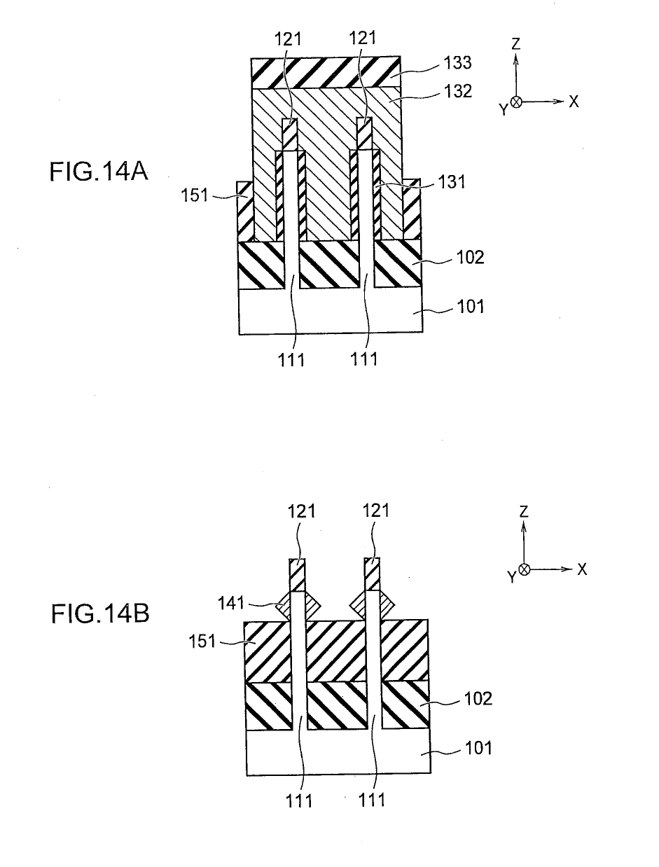

As shown in FIGS. 13A and 13B, the upper surface of the insulator 151 is then recessed by wet etching or RIE, so that the height of the upper surface of the insulator 151 is reduced. As a result, upper portions of the fins 111 are exposed. As shown in FIGS. 14A and 14B, an epitaxial layer 141 is then formed by SEG on each side surface S₁ of the exposed portions of the fins 111.

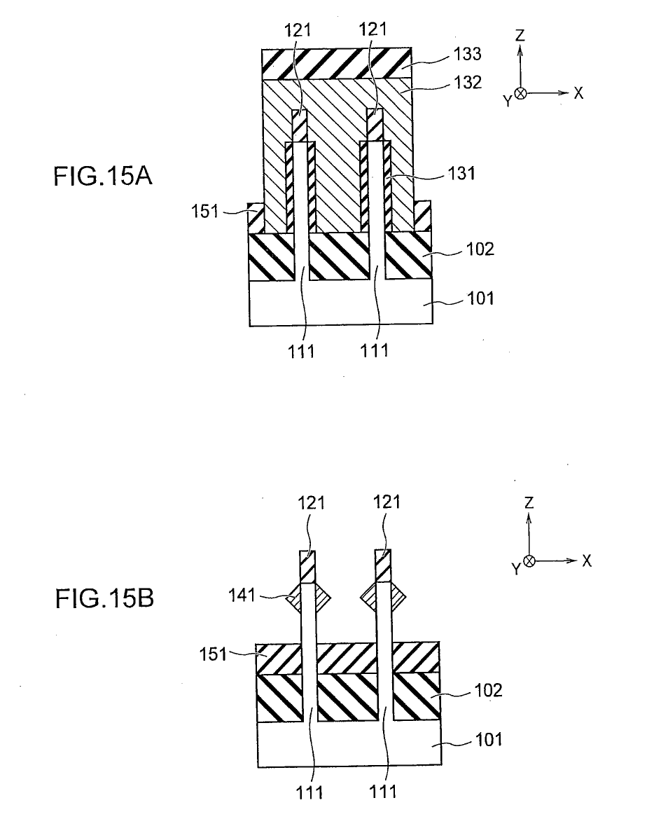

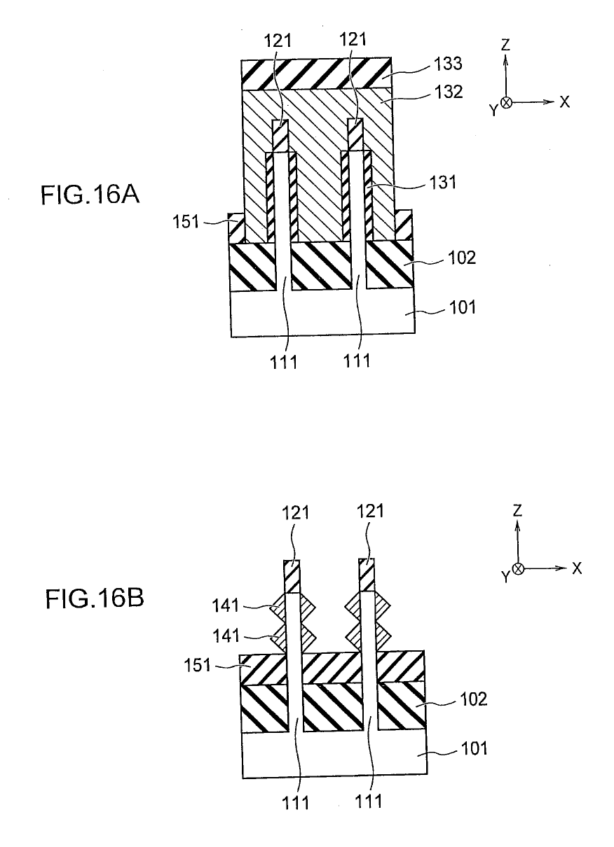

The same recessing processing as that in the process shown in FIGS. 13A and 13B, and the same epitaxial growth processing as that in the process shown in FIGS. 14A and 14B are again performed (FIGS. 15A to 16B). As a result, a second epitaxial layer 141 is formed on each side surface S₁ of the fins 111.

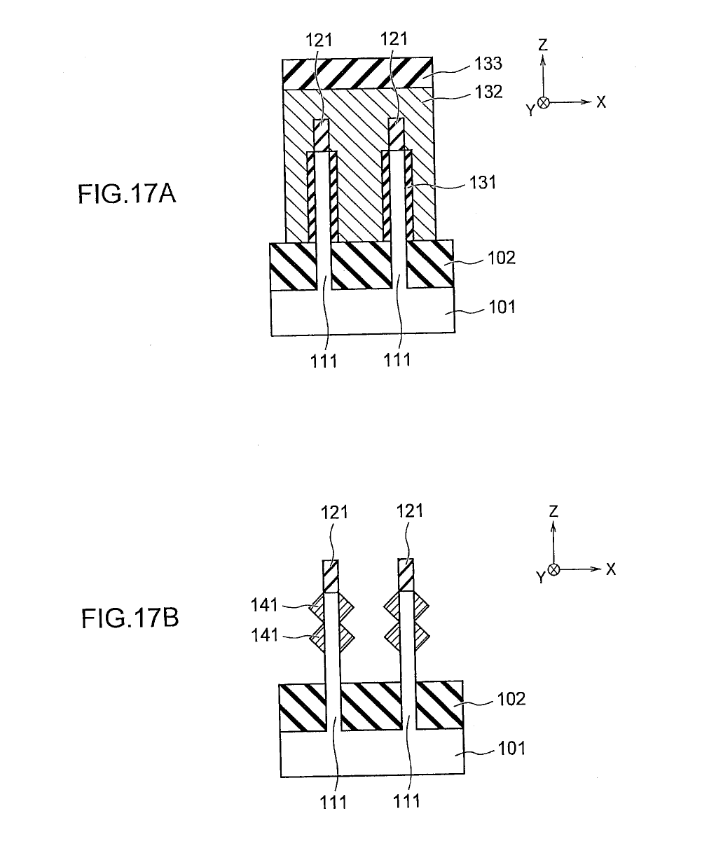

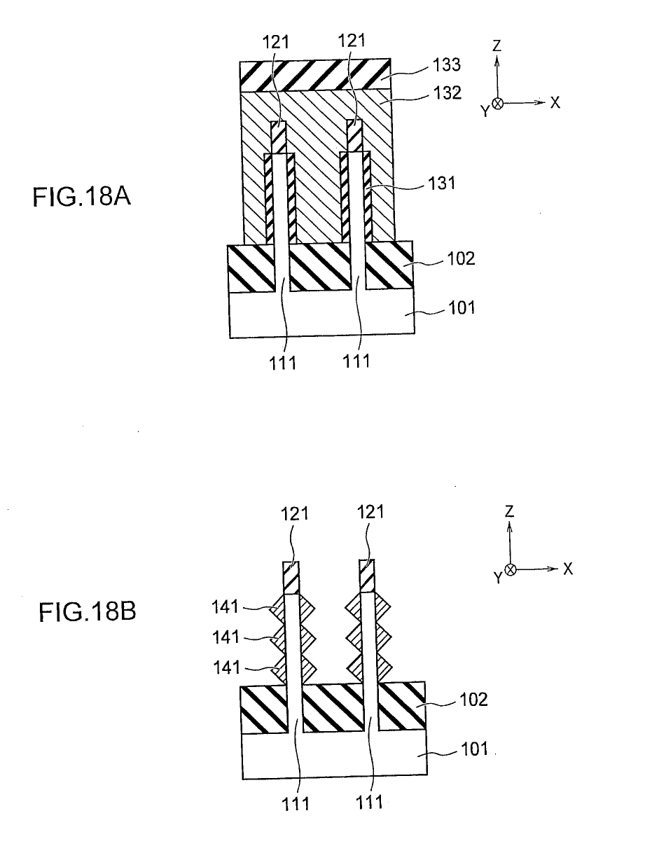

The recessing processing and the epitaxial growth processing are further performed once again (FIGS. 17A to 18B). As a result, a third epitaxial layer 141 is formed on each side surface S₁ of the fins 111.

In this way, the recessing processing to recess the upper surface of the insulator 151, and the epitaxial growth processing to form the epitaxial layer 141 are alternately repeated in the present embodiment. As a result, a plurality of epitaxial layers 141 are formed on each side surface S₁ of the fins 111 in order along the Z direction.

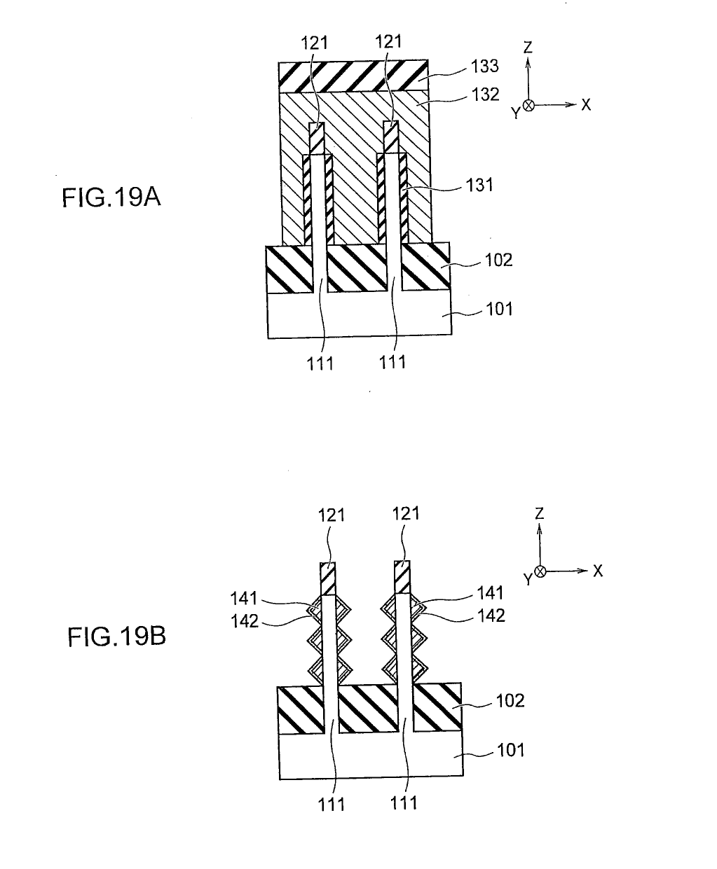

As shown in FIGS. 19A and 19B, the silicide layers 142 are then formed in the respective epitaxial layers 141. In this case, each epitaxial layer 141 may be entirely silicided, or may be only silicided partially. Alternatively, the process shown in FIGS. 19A and 19B may be omitted.

Thereafter, processes to form various inter layer dielectrics, contact plugs, via plugs, interconnect layers and the like are performed in the present embodiment. In this way, the semiconductor device shown in FIGS. 1A to 1C is manufactured.

The thicknesses T of the epitaxial layers 141 on each side surface S₁ of the fins 111 may be made substantially uniform or made non-uniform. The thicknesses T can be controlled by adjusting the recessing amount of the insulator 151 in the recessing processing. When the thicknesses T are made non-uniform, for example, the epitaxial layers 141 located at a lower position is set to have a larger thickness T. Such structure has an advantage that an inter layer dielectric can be easily embedded between the fins 111.

### (2) Effects of First Embodiment

Finally, the effects of the first embodiment will now be described.

As described above, a plurality of epitaxial layers 141 are formed on each side surface S₁ of the fins 111 in order along the height direction of the fins 111 in the present embodiment. Therefore, according to the present embodiment, large surface areas of the epitaxial layers 141 can be secured while the short-circuit between the fins 111 adjacent to each other can be avoided. According to the present embodiment, since the large surface areas of the epitaxial layers 141 can be secured while the height of the fins 111 can be set to be large, it is possible to realize high integration of transistors having high performance.

### Second Embodiment

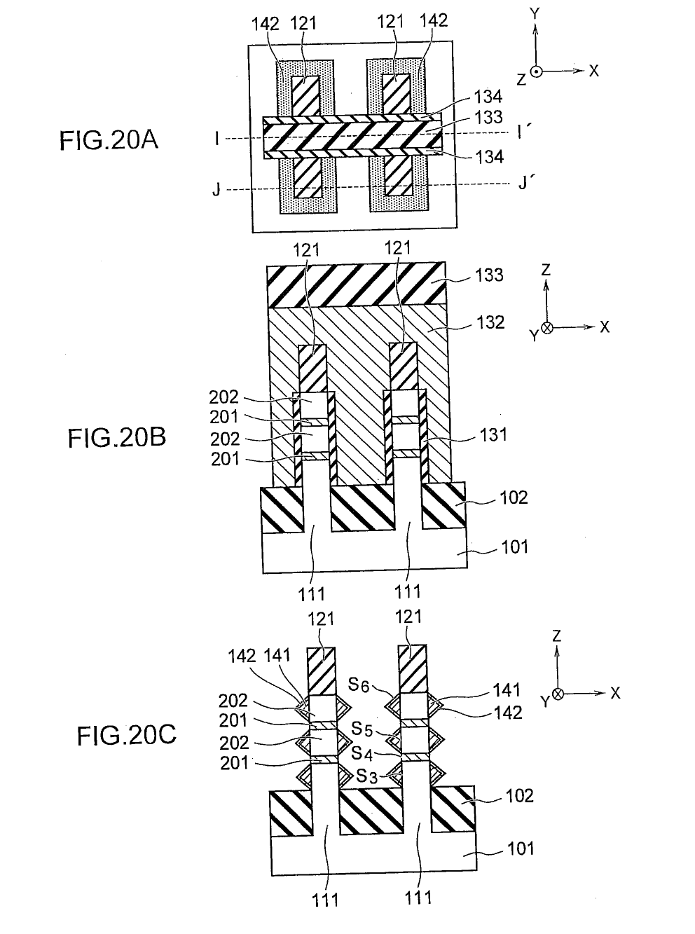

FIGS. 20A to 20C are a plan view and sectional views showing a structure of a semiconductor device of a second embodiment. FIG. 20A is a plan view showing a planar structure of the semiconductor device, and FIGS. 20B and 20C are sectional views taken along line I-I′ and line J-J′ shown in FIG. 20A, respectively.

In the present embodiment, each fin 111 includes a protruding portion of the semiconductor substrate 101, and one or more SiGe (silicon germanium) layers 201 and one or more Si (silicon) layers 202 alternatively stacked on the protruding portion. The SiGe layers 201 and the Si layers 202 are examples of first and second semiconductor layers, respectively. In the present embodiment, the thickness of the SiGe layers 201 is set smaller than the thickness of the Si layers 202.

Reference characters S₃, S₄ and S₅ denote side surfaces of the protruding portions of the semiconductor substrate 101, side surfaces of the SiGe layers 201, and side surfaces of the Si layers 202, respectively. The side surfaces S₃ to S₅ are (110) planes.

According to such stack-type fin structure, a stress parallel to the Y direction (i.e., parallel to the S/D direction) can be applied to the channel regions in the fins 111. Therefore, according to the present embodiment, the carrier mobility in the channel regions can be improved, and therefore the performance of the finFET can be further improved.

Each side surface of the fins 111 in the present embodiment includes one side surface S₃, two side surfaces S₄, and two side surfaces S₅. In addition, each of the side surface S₃ and the side surfaces S₅ is provided with an epitaxial layer 141. Therefore, three epitaxial layers 141 are formed on each side surface of the fins 111 in order along the Z direction in the present embodiment, similarly to the first embodiment. Therefore, according to the present embodiment, large surface areas of the epitaxial layers 141 can be secured while the short-circuit between the fins 111 adjacent to each other can be avoided.

Reference character S₆ denotes the facet surfaces of the epitaxial layers 141. The facet surfaces S₆ are (111) planes. The silicide layers 142 in the present embodiment are formed in the epitaxial layers 141 in the vicinity of the facet surfaces S₆.

Although each fin 111 in the present embodiment includes two SiGe layers 201 and two Si layers 202, each fin 111 may also include three or more SiGe layers 201 and three or more Si layers 202.

(1) Method of Manufacturing Semiconductor Device of Second Embodiment

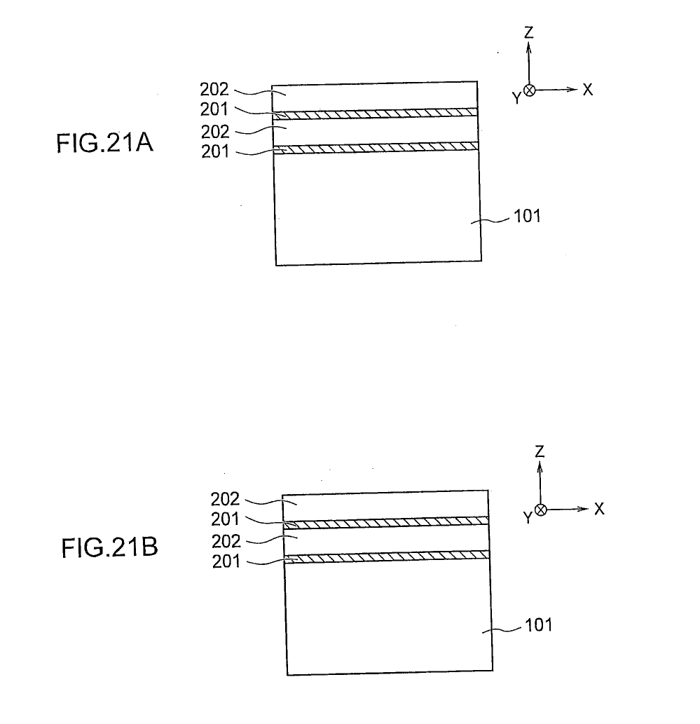

A method of manufacturing the semiconductor device of the second embodiment will now be described with reference to FIGS. 21A to 24B.

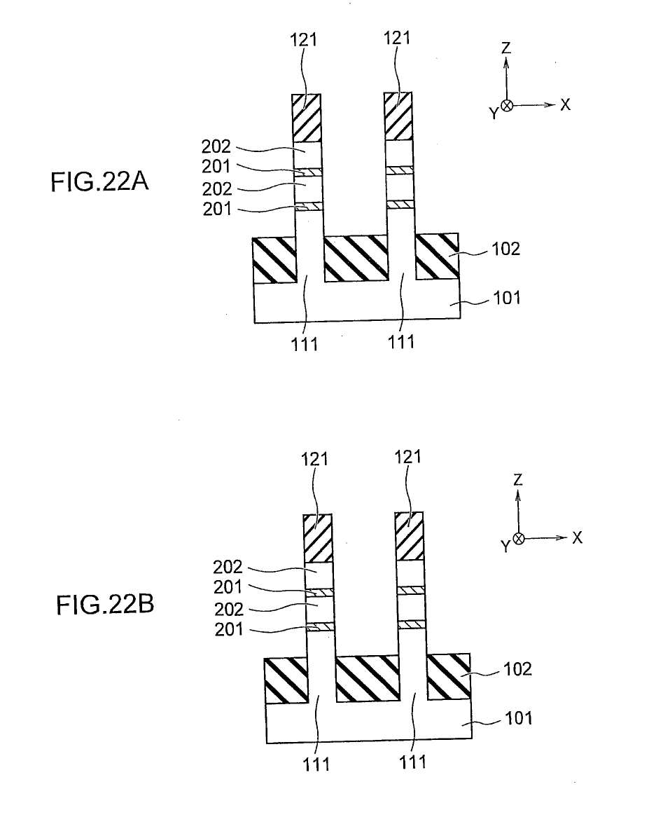

FIGS. 21A to 24B are sectional views showing the method of manufacturing the semiconductor device of the second embodiment. FIGS. 21A, 22A, . . . and 24A are sectional views taken along the line I-I′, and FIGS. 21B, 22B, . . . and 24B are sectional views taken along the line J-J′.

First, as shown in FIGS. 21A and 21B, one or more SiGe layers 201 and one or more Si layers 202 are alternately stacked on the semiconductor substrate 101.

The processes shown in FIGS. 2A to 5B are then performed to form the fins 111 on the surface of the semiconductor substrate 101, and to form the isolation insulators 102 between the fins 111. As a result, a structure shown in FIGS. 22A and 22B is obtained.

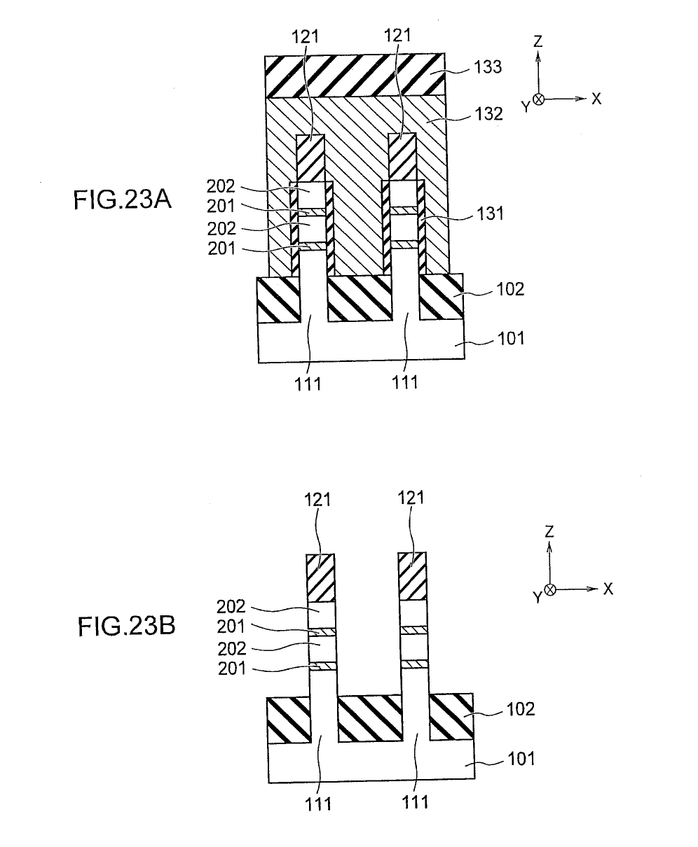

The processes shown in FIGS. 6A to 9Ba are then performed to form the gate electrode 132 on the side surfaces and the upper surfaces of the fins 111 via the gate insulators 131 and the hard mask layers 121. As a result, a structure shown in FIGS. 23A and 23B is obtained.

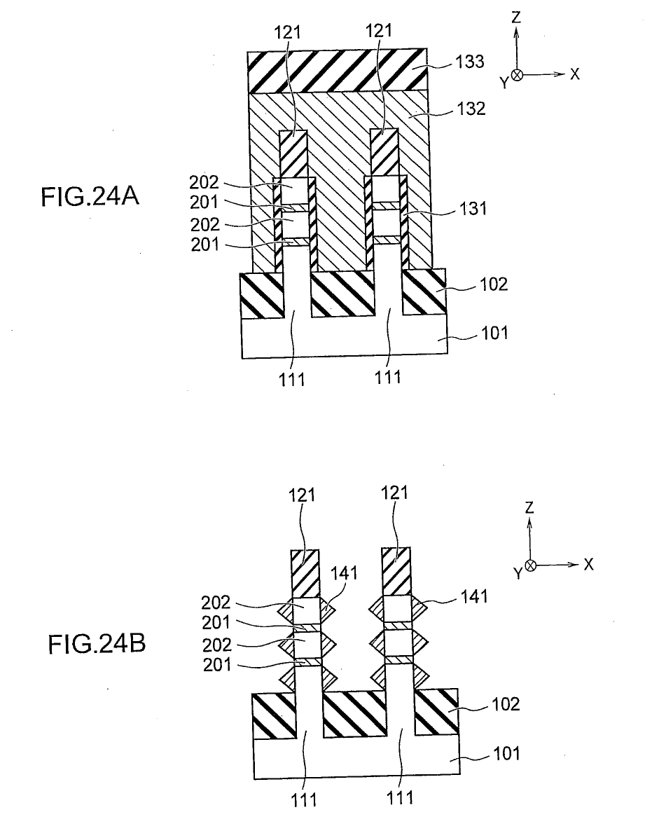

After the processes shown in FIGS. 10A to 11B are performed, the epitaxial layers 141 are formed on the side surfaces of the fins 111 by SEG (FIGS. 24A and 24B).

Due to a difference in lattice constant between Si and SiGe, the growth rate of the epitaxial Si layers on the surfaces of the Si layers 202 is different from the growth rate of the epitaxial Si layers on the surfaces of the SiGe layers 201. Specifically, the growth rate on the surfaces of the Si layers 202 is faster than the growth rate on the surfaces of the SiGe layers 201.

Therefore, in the process shown in FIGS. 24A and 24B, the epitaxial layers 141 are selectively formed on the side surfaces S₃ of the protruding portions of the semiconductor substrate 101, and on the side surfaces S₅ of the Si layers 202. As a result, the three epitaxial layers 141 are formed on each side surface of the fins 111 in order along the Z direction.

The process shown in FIGS. 19A and 19B is then performed to form the silicide layers 142 in the respective epitaxial layers 141. Thereafter, processes to form various inter layer dielectrics, contact plugs, via plugs, interconnect layers and the like are performed in the present embodiment. In this way, the semiconductor device shown in FIGS. 20A to 20C is manufactured.

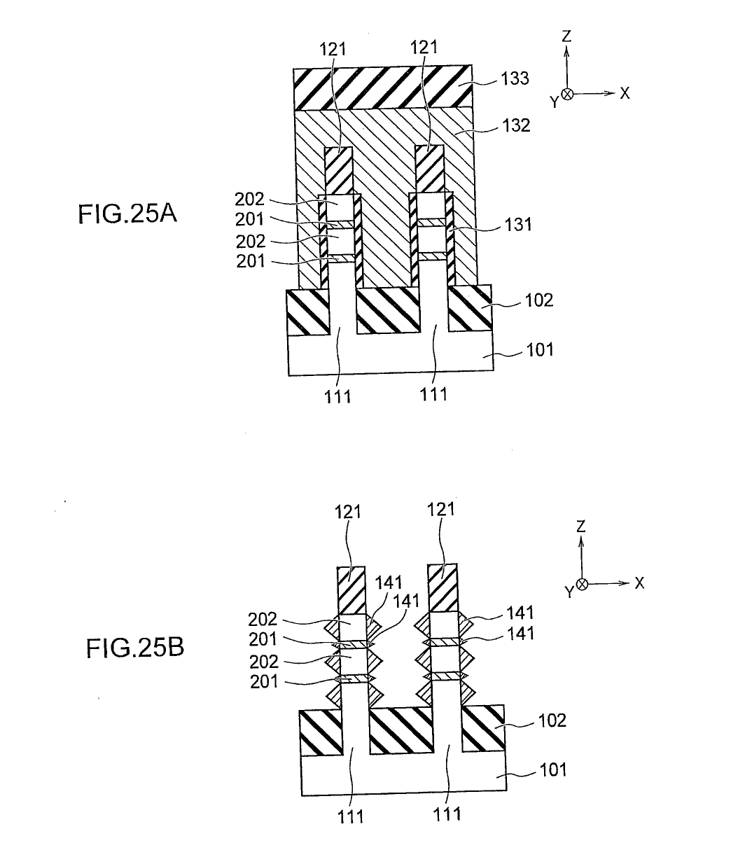

In the process shown in FIGS. 24A and 24B, the epitaxial Si layers are slightly grown also on the surfaces of the SiGe layers 201. Therefore, as shown in FIGS. 25A and 25B, small epitaxial layers 141 are also formed on the respective side surfaces S₄ of the SiGe layers 201. FIGS. 25A and 25B are sectional views showing the method of manufacturing the semiconductor device of the second embodiment in detail. The silicide layers 142 are also formed in those small epitaxial layers 141 by the subsequent silicide processing.

### (2) Effects of Second Embodiment

Finally, the effects of the second embodiment will now be described.

As described above, a plurality of epitaxial layers 141 are formed on each side surface of the fins 111 in order along the height direction of the fins 111 in the present embodiment. Therefore, according to the present embodiment, large surface areas of the epitaxial layers 141 can be secured while the short-circuit between the fins 111 adjacent to each other can be avoided, similarly to the first embodiment.

In addition, the stack-type fin structure is adopted in the present embodiment, and therefore the carrier mobility in the channel regions can be improved. This is because SiGe as the high mobility material is partially used in the channels, and because a stress is applied to the Si channels and the SiGe channels by the Si/SiGe stack structure. In addition, the stack-type fin structure is adopted in the present embodiment, and therefore a plurality of epitaxial layers 141 can be formed on each side surface of the fins 111 by one epitaxial growth process.

On the contrary, the first embodiment has an advantage that the process of alternately stacking the SiGe layers 201 and the Si layers 202 is not necessary.

### Third Embodiment

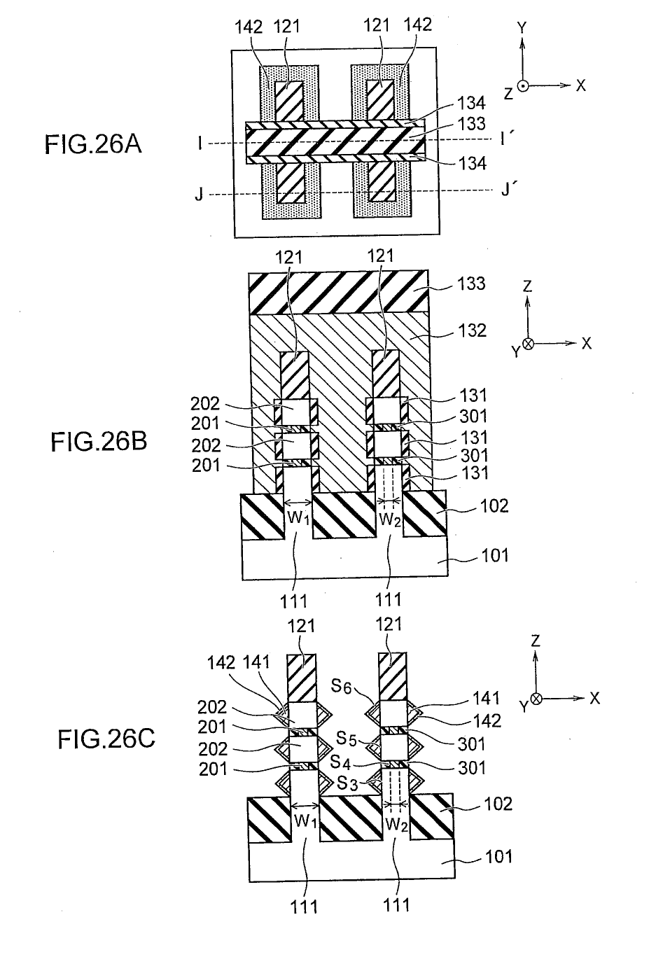

FIGS. 26A to 26C are a plan view and sectional views showing a structure of a semiconductor device of a third embodiment. FIG. 26A is a plan view showing a planar structure of the semiconductor device, and FIGS. 26B and 26C are sectional views taken along line I-I′ and line J-J′ shown in FIG. 26A, respectively.

Each fin 111 in the present embodiment includes a protruding portion of a semiconductor substrate 101, and one or more SiGe layers 201 and one or more Si layers 202 alternatively stacked on the protruding portion, similarly to the second embodiment.

However, in each fin 111 of the present embodiment, the side surfaces S₄ of the SiGe layers 201 are recessed with respect to the side surface S₃ of the protruding portion of the semiconductor substrate 101 and the side surfaces S₅ of the Si layers 202. In each fin 111 of the present embodiment, insulators 301 are further embedded in the regions where the SiGe layers 201 are recessed. The insulators 301 are, for example, silicon nitride layers.

Reference character W₁ denotes the X-directional width of the protruding portions of the semiconductor substrate 101 and the Si layers 202. Reference character W₂ denotes the X-directional width of the SiGe layers 201. In the present embodiment, the width W₂ is set smaller than the width W₁ (W₂<W₁).

If the width W₂ is made sufficiently smaller than the width W₁ in the present embodiment, the Si layers 202 can have structures like nanowires. A nanowire FET has better short channel effect immunity by its gate-around structure than the finFET. Therefore, according to the present embodiment, the reduction in gate length of the nanowire FET makes it possible to more highly integrate the transistors.

The gate insulators 131 in the present embodiment are formed only on the side surfaces S₃ and S₅ among the side surfaces S₃, S₄ and S₅. This is due to the fact that, when the gate insulators 131 are formed by thermal oxidation, the side surfaces S₄ are protected by the insulators 301 and are not oxidized. Since SiGe tends to be easily oxidized as compared with Si, the protection of the side surfaces S₄ by the insulators 301 is effective. Since the side surfaces S₄ are protected by the insulator 301, the epitaxial layers 141 are not formed on the side surfaces S₄.

(1) Method of Manufacturing Semiconductor Device of Third Embodiment

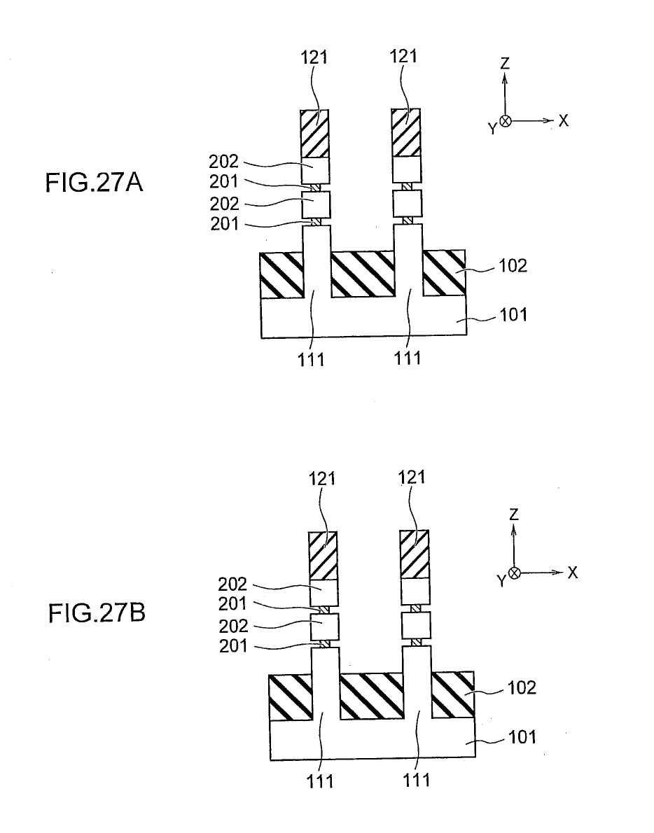

A method of manufacturing the semiconductor device of the third embodiment will now be described with reference to FIGS. 27A to 30B.

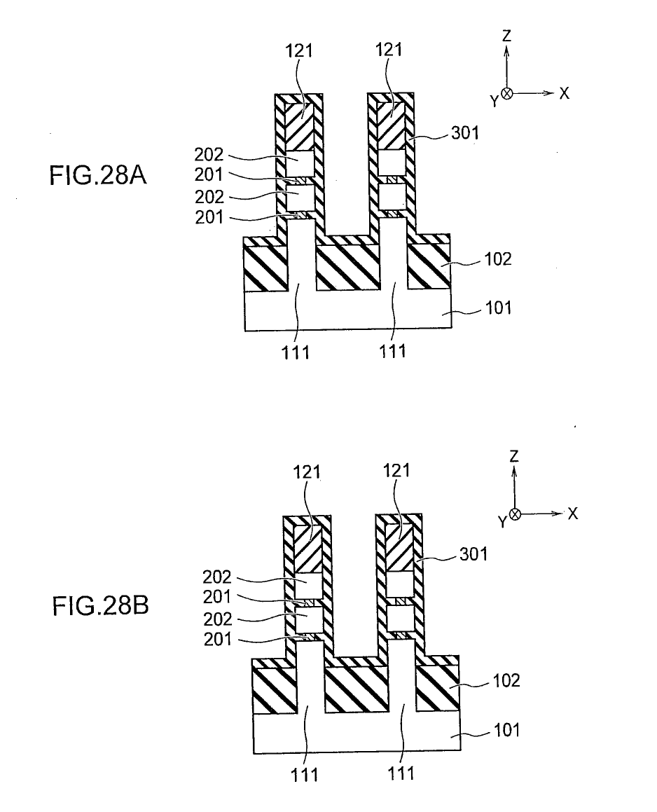

FIGS. 27A to 30B are sectional views showing the method of manufacturing the semiconductor device of the third embodiment. FIGS. 27A, 28A, . . . and 30A are sectional views taken along the line I-I′, and FIGS. 27B, 28B, . . . and 30B are sectional views taken along the line J-J′.

First, after the structure shown in FIGS. 22A and 22B is obtained, the SiGe layers 201 are selectively etched by wet etching (FIGS. 27A and 27B). As a result, the side surfaces S₄ of the SiGe layers 201 are recessed with respect to the side surfaces S₃ of the protruding portions of the semiconductor substrate 101, and the side surfaces S₅ of the Si layers 202.

As shown in FIGS. 28A and 28B, an insulator 301 is then deposited on the entire surface of the semiconductor substrate 101 by CVD. As a result, the surfaces of the isolation insulators 102, the fins 111, and the hard mask layers 121 are covered with the insulator 301.

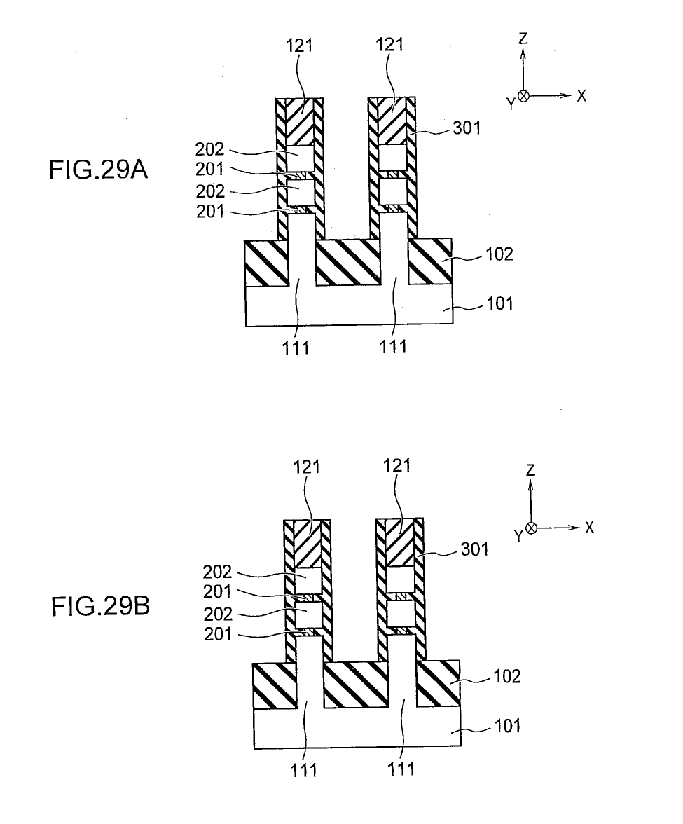

As shown in FIGS. 29A and 29B, the insulator 301 formed on the surfaces other than the side surfaces of the fins 111 and of the hard mask layers 121 is then removed by RIE.

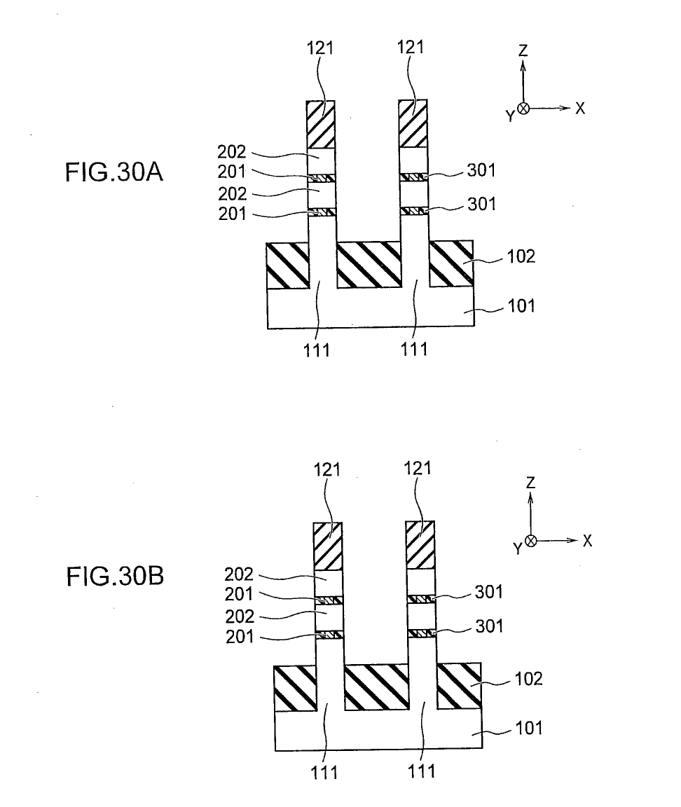

As shown in FIGS. 30A and 30B, the insulator 301 formed in the regions other than the recessed regions of the SiGe layers 201 is removed by wet etching. In this way, the structure in which the insulators 301 are embedded in the recessed portions is realized.

Thereafter, the processes shown in FIGS. 23A and 23B and the subsequent figures are performed similarly to the second embodiment. In addition, processes to form various inter layer dielectrics, contact plugs, via plugs, interconnect layers and the like is then performed in the present embodiment. In this way, the semiconductor device shown in FIGS. 26A to 26C is manufactured.

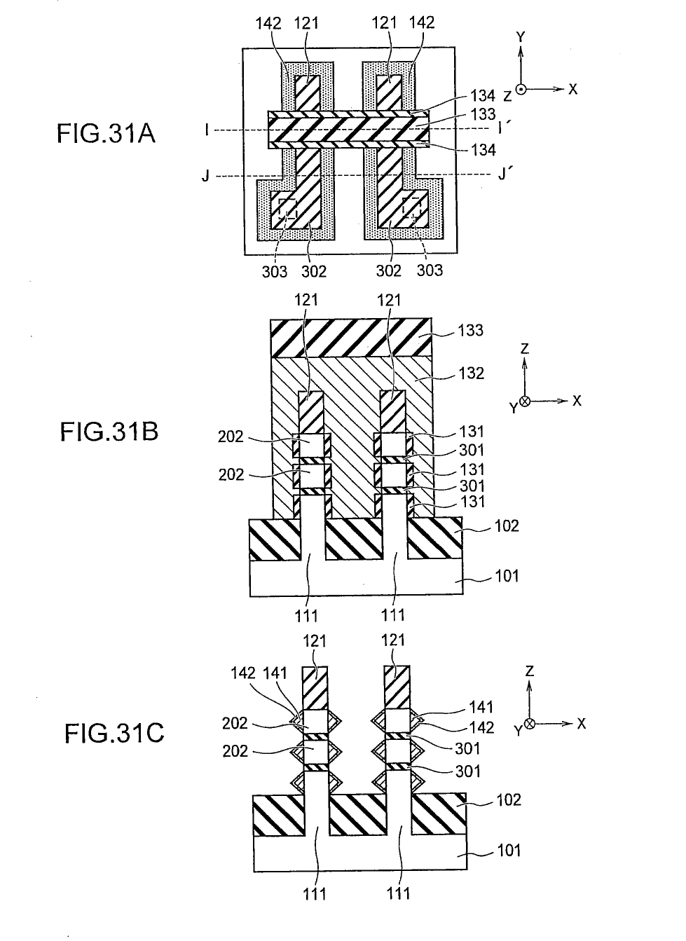

In the process shown in FIGS. 27A and 27B, the SiGe layers 201 in each fin 111 may be completely removed. In this case, a structure shown in FIGS. 31A to 31C is eventually realized. FIGS. 31A to 31C are a plan view and sectional views showing a structure of a semiconductor device of a modification of the third embodiment. Each fin 111 shown in FIGS. 31A to 31C includes a protruding portion of the semiconductor substrate 101, and one or more insulators 301 and one or more Si layers 202 alternately stacked on the protruding portion. In this way, according to the present modification, the Si layers 202 in each fin 111 can be processed into nanowires.

In the present modification, pad portions 302 are formed at tip portions of the respective fins 111 when the fins 111 are formed. In addition, the X-directional width and the Y-directional width of the pad portions 302 are set larger than the X-directional width W₁ of the fins 111. Such structure makes it possible to perform the process shown in FIGS. 27A and 27B in such a manner that the SiGe layers 201 in the fins 111 are completely removed and the SiGe layers 201 in the pad portions 302 are partially left. Reference numeral 303 shown in FIGS. 31A to 31C denotes regions where the SiGe layers 201 are partially left. In the present modification, the pad portions 302 having such SiGe residual regions 303 are formed, so that the Si layers 202 can be supported by the pad portions 302 after the SiGe layers 201 in the fins 111 are removed. The SiGe residual regions 303 are an example of connection semiconductor layers formed in the insulators 301 so as to connect the Si layers 202 to each other.

Although each fin 111 in the present modification is provided with a pad portion 302 at one tip portion of the fin 111, each fin 111 may be provided with pad portions 302 at both tip portions of the fin 111.

### (2) Effects of Third Embodiment

Finally, the effects of the third embodiment will now be described.

As described above, a plurality of epitaxial layers 141 are formed on each side surface of the fins 111 in order along the height direction of the fins 111 in the present embodiment. Therefore, according to the present embodiment, large surface areas of the epitaxial layers 141 can be secured while the short-circuit between the fins 111 adjacent to each other can be avoided, similarly to the first and second embodiments.

In addition, the side surfaces S₄ of the SiGe layers 201 are recessed with respect to the side surfaces S₃ of the protruding portions of the semiconductor substrate 101 and the side surfaces S₅ of the Si layers 202 in the present embodiment. Therefore, according to the present embodiment, the short channel effect of the transistors can be suppressed. As a result, it makes possible to more highly integrate the transistors by reducing the gate length in the present embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
a fin disposed on a surface of the semiconductor substrate, and having a side surface of a (110) plane;
a gate insulator disposed on the side surface of the fin;
a gate electrode disposed on the side surface and an upper surface of the fin via the gate insulator; and
a plurality of epitaxial layers disposed on the side surface of the fin in order along a height direction of the fin.

2. The device of claim 1, wherein the epitaxial layers have facet surfaces of (111) planes.

3. The device of claim 1, further comprising silicide layers disposed in the epitaxial layers.

4. The device of claim 1, wherein
the fin includes one or more first semiconductor layers and one or more second semiconductor layers alternately stacked on the semiconductor substrate, and
the epitaxial layers are disposed on side surfaces of respective second semiconductor layers.

5. The device of claim 4, wherein the epitaxial layers are further disposed on side surfaces of respective first semiconductor layers.

6. The device of claim 4, wherein thicknesses of the first semiconductor layers are smaller than thicknesses of the second semiconductor layers.

7. The device of claim 4, wherein side surfaces of the first semiconductor layers are recessed with respect to the side surfaces of the second semiconductor layers in the fin.

8. The device of claim 7, wherein an insulator is embedded in a region where the side surfaces of the first semiconductor layers are recessed in the fin.

9. The device of claim 1, wherein
the fin includes one or more insulators and one or more semiconductor layers alternately stacked on the semiconductor substrate, and
the epitaxial layers are disposed on side surfaces of respective semiconductor layers.

10. The device of claim 1, further comprising a pad portion disposed at a tip portion of the fin,
wherein the pad portion includes the one or more insulators, the one or more semiconductor layers, and one or more connection semiconductor layers disposed in the insulators to connect the semiconductor layers with each other.

11. A method of manufacturing a semiconductor device, the method comprising:
forming a fin having a side surface of a (110) plane on a surface of a semiconductor substrate;
forming a gate electrode on a side surface and an upper surface of the fin via a gate insulator formed on the side surface of the fin;
covering the fin with an insulator; and
forming a plurality of epitaxial layers on the side surface of the fin in order along a height direction of the fin, by alternately repeating processing of reducing a height of an upper surface of the insulator and processing of forming an epitaxial layer on the side surface of the fin.

12. The method of claim 11, wherein the epitaxial layers are formed to have facet surfaces of (111) planes.

13. The method of claim 11, further comprising forming silicide layers in the epitaxial layers.

14. The method of claim 11, wherein
the fin is formed to include one or more first semiconductor layers and one or more second semiconductor layers alternately stacked on the semiconductor substrate, and
the epitaxial layers are formed on side surfaces of respective second semiconductor layers.

15. The method of claim 14, wherein the epitaxial layers are further formed on side surfaces of respective first semiconductor layers.

16. The method of claim 14, wherein thicknesses of the first semiconductor layers are set smaller than thicknesses of the second semiconductor layers.

17. The method of claim 14, further comprising recessing side surfaces of the first semiconductor layers with respect to the side surfaces of the second semiconductor layers in the fin.

18. The method of claim 17, further comprising embedding an insulator in a region where the side surfaces of the first semiconductor layers are recessed in the fin.

19. The method of claim 11, wherein
the fin is formed to include one or more insulators and one or more semiconductor layers alternately stacked on the semiconductor substrate, and
the epitaxial layers are formed on side surfaces of respective semiconductor layers.

20. The method of claim 11, further comprising forming a pad portion at a tip portion of the fin,
wherein the pad portion is formed to include the one or more insulators, the one or more semiconductor layers, and one or more connection semiconductor layers formed in the insulators to connect the semiconductor layers with each other.
